(19) United States
(12) Patent Application Publication
(10) Pub. No.: US 2024/0324464 A1
(43) Pub. Date: Sep. 26, 2024

(54) PIEZO ELEMENT DIAGNOSIS DEVICE, PIEZO ELEMENT DIAGNOSIS METHOD, PIEZO ELEMENT DIAGNOSIS PROGRAM, FLUID CONTROL DEVICE, AND VAPORIZATION SYSTEM

(71) Applicant: HORIBA STEC, Co., Ltd., Kyoto-shi (JP)

(72) Inventors: Akihiro TAGUCHI, Kyoto-shi (JP); Chihiro HAMADA, Kyoto-shi (JP)

(21) Appl. No.: 18/597,775

(22) Filed: Mar. 6, 2024

(30) Foreign Application Priority Data
Mar. 23, 2023 (JP) 2023-046867

(51) Int. Cl. H10N 30/80; G01N 29/22

(52) U.S. Cl. CPC H10N 30/802; G01N 29/222

(57) ABSTRACT

The present invention enables a piezo element to be replaced or maintained at an appropriate timing, and is a piezo element diagnosis device for making a diagnosis of a piezo element incorporated in a piece of equipment, and includes a driving information acquisition unit that acquires driving information of the piezo element, and a life calculation unit that calculates a consumed life or a remaining life of the piezo element based on the driving information.

The present application claims priority to Japan Patent Application No. 2023-046867 filed Mar. 23, 2023, which is incorporated herein by reference in its entirety.

### BACKGROUND OF THE INVENTION

### 1. Technical Field

The present invention relates to a piezo element diagnosis device, a piezo element diagnosis method, and a piezo element diagnosis program. The present invention also relates to a fluid control device that uses a piezo element diagnosis device, and a vaporization system that uses a piezo element diagnosis device.

### 2. Description of the Related Art

As an example of a fluid control valve incorporated in a mass flow controller (MFC) or the like, there is a piezo valve that uses a piezo element. Such a piezo valve includes a piezo element that is caused to expand and to contract by receiving an application of a voltage, whereby driving a valve body with respect to a valve seat.

It is known that the piezo element degrades by different degrees depending on factors such as the level of the voltage to be applied thereto and the ambient temperature where the piezo element is used. In fact, piezo valves used in systems such as vaporization systems are intended to control vapor resultant of the vaporization, so the piezo elements are subjected to a high-ambient temperature during the use. Therefore, such piezo elements degrade (fail) in a shorter time period than those used in the ordinary ambient temperature.

Conventionally, such piezo elements are replaced based on their mean time to failure (MTTF), as disclosed in JP 2003-8092 A. Such a MTTF represents the time for a piezo element to fail, and is calculated in advance.

$$MTTF = {MTTF}_{0} \times Kt \times Kv$$

Where MTTF₀ is a MTTF that is used as a reference, and is a value obtained in advance through reliability tests;
Kt is an acceleration coefficient given by a certain operating temperature T (=1.4^{(T0-T0/10})
Kv is an acceleration coefficient given by a certain operating voltage V (=(V₀/V)^{2.5});
T₀ is a reference temperature under which the MTTF₀ is obtained; and
V₀ is a reference voltage used under which the MTTF₀ is obtained.

However, with the mean time to failure (MTTF) described above, life can only be calculated under a specific temperature (T) and a specific voltage (V). Therefore, if operating conditions of the piezo valve change (e.g., if the applied voltage or the operating temperature changes), the timing of replacement thus determined may not be quite accurate. As a result, the piezo element may fail before the arrival of the calculated mean time to failure. It is also possible for the piezo element to be replaced too early, based on the mean time to failure.

### PRIOR ART DOCUMENT

### Patent Document

JP 2003-8092 A

### SUMMARY OF THE INVENTION

The present invention has been made to solve the technical problem described above, and an object of the present invention is to enable a piezo element to be replaced or maintained at an appropriate timing.

That is, a piezo element diagnosis device according to the present invention is a piezo element diagnosis device for making a diagnosis of a piezo element incorporated in a piece of equipment, and includes a driving information acquisition unit that acquires driving information of the piezo element, and a life calculation unit that calculates a consumed life or a remaining life of the piezo element based on the driving information.

With such a piezo element diagnosis device, because the consumed life or the remaining life of the piezo element is calculated based on the driving information, the piezo element can be replaced or maintained at an appropriate timing even when there is a change in the conditions under which the piezo element is used.

Preferably, the life calculation unit calculates the consumed life or the remaining life based on an expected life of the piezo element, the expected life being obtained in advance, as well as on the driving information.

As to the expected life of the piezo element, a reference life obtained in in advance through a reliability test may be used as the expected life. The reference life herein is a reference mean time to failure (hereinafter, MTTFs) obtained by carrying out reliability tests in advance. This MTTF indicates a mean value of the time lengths from when piezo elements are activated to when the piezo elements fail.

With this configuration, because the life (MTTFs), which serves as the reference for the piezo element, is used, the consumed life or the remaining life can be obtained more accurately.

As a specific embodiment of the driving information, preferably, the driving information includes at least one of a driving voltage of the piezo element and a temperature of the piezo element, and the life calculation unit calculates the consumed life or the remaining life based on the expected life and at least one of the driving voltage of the piezo element and the temperature of the piezo element.

With this configuration, because the consumed life or the remaining life is calculated based on the driving voltage or the temperature that tends to have a great impact on the life of the piezo element, a more accurate consumed life or remaining life can be obtained.

As a specific embodiment of the life calculation unit, it is conceivable that the life calculation unit calculates a cumulative consumed life or the remaining life from when use of the piezo element is started, once in every time interval.

Conventionally, a mean time to failure giving a consideration to usage conditions (hereinafter, MTTFr) can only be obtained as a value specific to a certain operating temperature (T) and operating voltage (V).

By contrast, according to the present invention, the life calculation unit is configured to calculate a unit consumed life that is the life consumed per unit time, once in every time interval.

As one example, the unit consumed life is calculated as a fraction the denominator of which is MTTFr calculated from a representative driving voltage and a representative temperature in the corresponding time interval, and the numerator of which is the time length of the time interval. In this manner, it is possible to obtain the unit consumed life (hereinafter, referred to as MTTFm), which is the consumed life per unit time.

A plurality of MTTFm obtained for the respective time intervals (hereinafter, MTTFc) are added to obtain a sum that represents the cumulative consumed life from when the use of the piezo element is started. When the MTTFc reaches one, the expected life (mean time to failure) giving consideration of the usage conditions expires.

As a specific method for calculating the consumed life or the remaining life, the driving information acquisition unit may acquire the driving information once in every sampling time period, and the life calculation unit may calculate the consumed life or the remaining life by using a representative value of a plurality of pieces of the driving information.

Preferably, the piezo element diagnosis device according to the present invention further includes: a comparison unit that compares the consumed life or the remaining life calculated by the life calculation unit with a predetermined threshold; and an alarm output unit that outputs an alarm based on a result of a comparison performed by the comparison unit.

With this configuration, it is possible to provide notifications such as those of the timings for replacement or maintenance of the piezo element, so that the user can be prompted to perform tasks such as replacement or maintenance of the piezo element.

As a specific aspect of a management accompanying the replacement of the piezo element, the piezo element diagnosis device according to the present invention preferably further includes: a replacement signal receiving unit that receives a replacement signal indicating that a subject piezo element has been replaced; and a reset unit that resets the consumed life or the remaining life calculated by the life calculation unit upon receiving the replacement signal.

Preferably, the piezo element diagnosis device according to the present invention further includes an automatic recognition unit that automatically recognizes a piezo element after replacement when a subject piezo element is replaced, and the life calculation unit preferably calculates a consumed life or a remaining life of the piezo element after replacement.

With this configuration, because the replaced piezo element is automatically recognized, it is possible to reduce management tasks accompanying the replacement with a new piezo element.

Preferably, the piezo element diagnosis device further includes a life prediction unit that calculates a future consumed life or remaining life based on a change in the consumed life or the remaining life obtained by the life calculation unit.

With this configuration, it is possible to prepare a new piezo element in advance, and create a plan for a replacement or a maintenance of the piezo element in advance.

A piezo element diagnosis method according to the present invention is a piezo element diagnosis method for diagnosing a piezo element incorporated in a piece of equipment, the piezo element diagnosis method including: acquiring driving information of the piezo element; and calculating a consumed life or a remaining life of the piezo element based on the driving information.

A piezo element diagnosis program according to the present invention is a piezo element diagnosis program for diagnosing a piezo element incorporated in a piece of equipment, the program causing a computer to exert a function as a driving information acquisition unit that acquires driving information of the piezo element, and a function as a life calculation unit that calculates a consumed life or a remaining life of the piezo element based on the driving information.

The piezo element diagnosis program may be electronically distributed or may be recorded in a program recording medium such as a CD, a DVD, or a flash memory. Alternatively, the piezo element diagnosis program may be executed as edge processing (processing in which raw data is uploaded to a cloud and the server is caused to perform the calculation). With the configuration for executing edge processing, data can be accumulated. Therefore, in the calculation of the remaining life, too, this configuration provides an advantage that the entire data is made available for reference.

A fluid control device according to the present invention includes: a piezo valve that uses a piezo element to drive a valve body with respect to a valve seat; a valve control unit that controls a degree by which the piezo valve is opened; and the piezo element diagnosis device described above.

Furthermore, a vaporization system according to the present invention includes: a vaporizer unit that vaporizes a liquid raw material; a fluid control device that controls a flow rate of vapor resultant of vaporization of the vaporizer unit; and the piezo element diagnosis device described above.

As described above, according to the present invention, because the consumed life or the remaining life of a piezo element is calculated based on the driving information, the piezo element can be replaced or maintained at an appropriate timing even when the conditions of use of the piezo element change.

### BRIEF DESCRIPTION OF THE DRAWINGS

FIG. 1 is a diagram schematically illustrating a configuration of a vaporization system according to an embodiment of the present invention;

FIG. 2 is a functional block diagram of a control device and a piezo element diagnosis device according to the embodiment;

FIG. 3 is a functional block diagram of a control device and a piezo element diagnosis device according to a modified embodiment; and

FIG. 4 is a functional block diagram of a control device and a piezo element diagnosis device according to another modified embodiment.

### DETAILED DESCRIPTION

A vaporization system incorporating a piezo element diagnosis device according to one embodiment of the present invention will now be explained with reference to some drawings. Note that all of the drawings described below are schematic representations with some omissions and exaggerations made as appropriate, in order to facilitate understanding. The same elements are denoted by the same reference numerals, and the descriptions thereof will be omitted as appropriate.

### <1. Basic Configuration of Vaporization System 100>

A vaporization system 100 according to the embodiment is incorporated in a semiconductor manufacturing line, for example, and is configured to supply vapor into a chamber, in which a semiconductor manufacturing process is performed, at a predetermined flow rate.

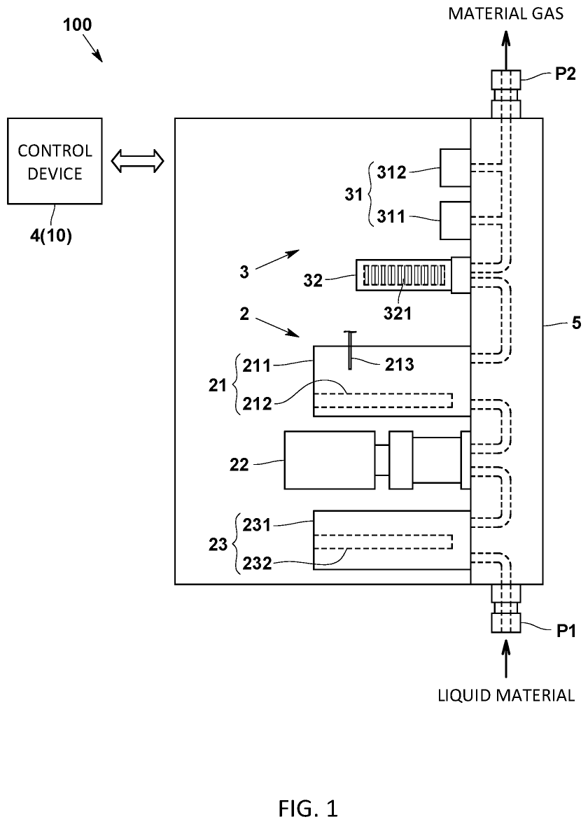

Specifically, as illustrated in FIG. 1, the vaporization system 100 includes a vaporizer unit 2 that vaporizes a liquid material, a mass flow controller 3 that controls the flow rate of the resultant vapor from the vaporizer unit 2 (hereinafter, a material gas), and a control device 4 that controls operations of units such as the vaporizer unit 2 and the mass flow controller 3.

The vaporizer unit 2 includes a vaporizer 21 that vaporizes a liquid material by baking, for example, a supply amount controller 22 that controls the amount of the liquid material to be supplied into the vaporizer 21, and a preheater 23 that preheats the liquid material to be supplied to the vaporizer 21 to a predetermined temperature. The vaporizer 21, the supply amount controller 22, and the preheater 23 are mounted on a main body block 5 delineating a channel. The preheater 23 in the vaporizer unit 2 may be omitted.

The vaporizer 21 includes a storage container 211 for storing a liquid material, and a vaporization heater 212 provided in the storage container 211 to vaporize the liquid material. The storage container 211 is provided with a liquid level sensor 213 for detecting the amount of the stored liquid material. As the liquid level sensor 213, various types of liquid level sensor may be used. Examples of such liquid level sensors include a liquid level sensor based on self-heating approach, a liquid level sensor based on liquid temperature measurements, a magnetic liquid level sensor, a capacitance liquid level sensor, and an ultrasonic liquid level sensor.

The supply amount controller 22 is an electromagnetic on-off valve. The electromagnetic on-off valve 22 is configured to open or to close the channel formed inside the main body block 5, to supply or to stop supplying of the liquid material into the vaporizer 21. Examples of the supply amount controller 22 include a control valve such as a piezo valve, and a mass flow controller.

The preheater 23 includes a preheating block 231 forming a channel through which the liquid material flows, and a preheating heater 232 provided to the preheating block 231 for preheating the liquid material. The liquid material is heated by the preheater 23 to a temperature immediately below the temperature at which the material vaporizes (below its boiling point).

With the vaporizer unit 2 configured as described above, the liquid material is introduced via a liquid material inlet P1 into the main body block 5, and is preheated by flowing through the channel inside the preheating block 231 of the preheater 23. The electromagnetic on-off valve 22 is then controlled to introduce the liquid material having been preheated by the preheater 23, into the vaporizer 21. With the liquid material thus kept being stored in the vaporizer 21 and allowing the liquid material to vaporize continuously, the vaporizer 21 is kept generating material gas, and feeding the material gas into the mass flow controller 3, continuously.

The mass flow controller 3 will now be explained.

The mass flow controller 3 is provided downstream of the vaporizer unit 2, and controls the flow rate of the material gas generated by the vaporizer unit 2. Specifically, the mass flow controller 3 includes a fluid detector 31 that detects the material gas flowing through the channel, and a piezo valve 32 that controls the flow rate of the material gas flowing through the channel.

The fluid detector 31 and the piezo valve 32 are mounted on the main body block 5. Specifically, the fluid detector 31 and the piezo valve 32 are mounted on the main body block 5, on the downstream side of the vaporizer unit 2. The main body block 5 is also installed in a facility such as a semiconductor manufacturing line in the orientation in which the liquid material inlet P1 is on the lower side and the material gas outlet port P2 is on the upper side, with the longitudinal direction of the main body block extending along the up-down direction (vertical direction).

The fluid detector 31 includes a first pressure sensor 311 that is a capacitance pressure sensor, for example, for detecting the pressure upstream of a fluid resistance (not illustrated) provided in the channel of the main body block 5, and a second pressure sensor 312 that is a capacitance pressure sensor, for example, for detecting the pressure downstream of the fluid resistance. The fluid detector 31 according to the embodiment provides a differential pressure flow sensor, but may be a thermal flow sensor using a pair of heating resistors.

The piezo valve 32 controls the flow rate of the material gas flowing through the channel inside the main body block 5. The piezo valve 32 drives the valve body with respect to the valve seat using the piezo element 321. The piezo valve 32 according to the embodiment is of what is called a normally open valve but may be of a normally closed valve.

The control device 4 will now be described.

The control device 4 is configured to control operations of the vaporizer unit 2, the mass flow controller 3, and the like to supply the vapor at a predetermined flow rate into the chamber.

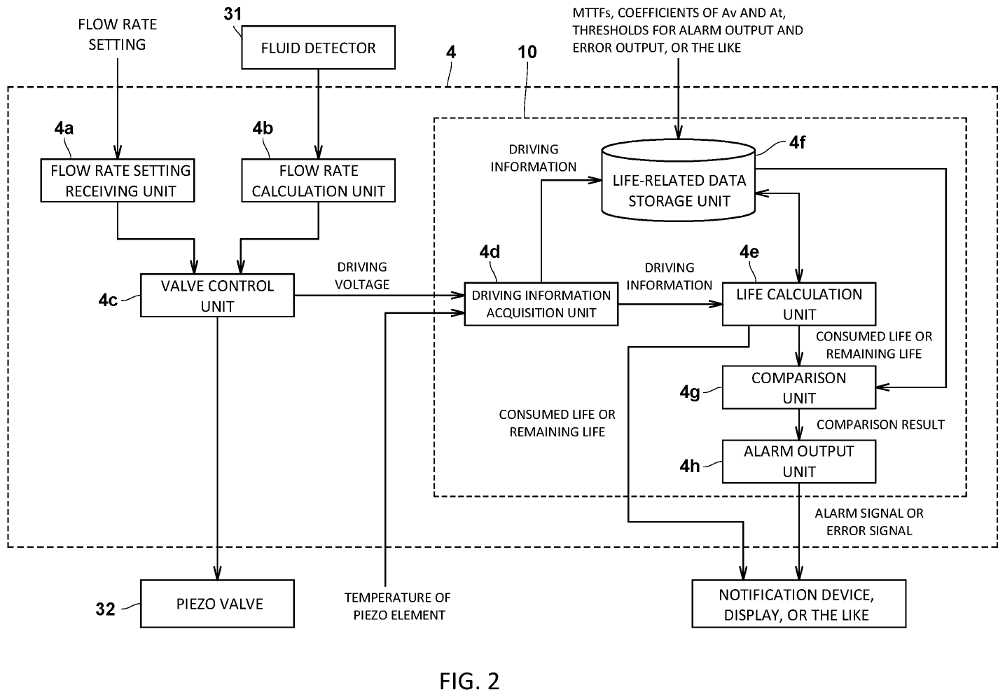

Specifically, the control device 4 is a computer including a CPU, a memory, an AC/DC converter, and an input unit, and by causing the CPU and its peripheral device to cooperate with each other according to a program stored in the memory, the control device 4 functions as a flow rate setting receiving unit 4a, a flow rate calculation unit 4b, a valve control unit 4c, and the like, as illustrated in FIG. 2. The control device 4 also controls the electromagnetic on-off valve 22, based on a detection signal from the liquid level sensor 213.

The flow rate setting receiving unit 4a receives a flow rate setting signal indicating a flow rate setting transmitted via an input operation made by a user on an input unit, such as a keyboard or other types of device.

The flow rate calculation unit 4b acquires an output signal from the fluid detector 31, and calculates the flow rate of the material gas discharged from the vaporizer unit 2. The flow rate calculation unit 4b may be provided in the mass flow controller 3, thereby forming a flow rate sensor with the fluid detector 31.

The valve control unit 4c controls the piezo valve 32 based on the flow rate setting and the flow rate measurement calculated by the flow rate calculation unit 4b. The valve control unit 4c outputs a drive signal to the piezo valve 32 to feedback-control the degree by which the valve is opened, so that the flow rate measurement is adjusted to the rate set in the flow rate setting.

### <2. Function of Diagnosing Piezo Element Life>

The control device 4 according to the embodiment has a piezo element diagnosis function for diagnosing the piezo element incorporated in the piezo valve 32. In other words, the control device 4 implements the function of the piezo element diagnosis device 10.

Specifically, the control device 4 functions as a driving information acquisition unit 4d, a life calculation unit 4e, a life-related data storage unit 4f, a comparison unit 4g, an alarm output unit 4h, and the like in accordance with a piezo element diagnosis program stored in the memory.

The driving information acquisition unit 4d acquires driving information such as a driving history of the piezo element 321. Furthermore, the driving information acquisition unit 4d acquires driving information once in every predetermined sampling time period (for example, 100 msec). The driving information according to the embodiment is the driving voltage applied to the piezo element 321 and the temperature of the piezo element 321.

The driving voltage can be acquired from the valve control unit 4c or a drive circuit (not illustrated). The temperature of the piezo element 321 can be acquired from a temperature sensor (not illustrated) provided around the piezo element 321. Note that the temperature of the piezo element 321 may be temperatures such as an ambient temperature of the piezo element 321, a temperature of the piezo valve 32, and an ambient temperature of the piezo valve 32, in addition to the temperature of the piezo element 321 itself.

The life calculation unit 4e calculates the consumed life or the remaining life of the piezo element 321 based on the driving information. The life calculation unit 4e according to the embodiment calculates the consumed life or the remaining life of the piezo element 321 based on at least one of the driving voltage of the piezo element 321 and the temperature of the piezo element 321.

The consumed life of the piezo element 321 herein includes a cumulative consumed life that is a consumed life from when the use is started (the first use after the shipment) or a unit consumed life that is a consumed life per unit time. The consumed life is, for example, a consumed time (operation time), or a consumed ratio (ratio to the expected life). Examples of the operation time include simply the time for which the piezo element is operated, or a converted operation time that is a conversion to the time for which the piezo element is used under a certain driving condition (e.g., a driving voltage, a driving temperature), for example. The consumed life according to the embodiment is obtained from a reference mean time to failure (MTTFs) obtained in advance through reliability tests, as will be described later. The remaining life is a remaining time (operation time) or a remaining ratio (ratio with respect to the expected life) calculated from the cumulative consumed life (cumulative consumed life).

Specifically, the life calculation unit 4e calculates the consumed life or the remaining life based on the expected life of the piezo element 321, the expected life being obtained in advance, as well as on the driving information. The life calculation unit 4e according to the embodiment calculates the consumed life or the remaining life based on the expected life obtained in advance, the driving voltage of the piezo element 321, and the temperature of the piezo element 321. As to the expected life obtained in advance, a reference mean time to failure (MTTFs) obtained in advance through the reliability tests is used as the expected life.

The life calculation unit 4e calculates the consumed life or the remaining life once in every time interval (e.g., one hour) that includes a plurality of sampling time periods (100 msec). The time interval may remain the same or differ every time, or may be changed, in accordance with the elapsed time from the start of use.

The life calculation unit 4e also calculates the consumed life or the remaining life by using representative values of a plurality of pieces of driving information (the driving voltage and the temperature) included in each time interval. The representative value of the plurality of pieces of driving information may be an average, a median, or a calculated value obtained from the plurality of pieces of driving information.

The life calculation unit 4e calculate a unit consumed life that is the life consumed per unit time, once in every time interval. Specifically, the life calculation unit 4e calculates a unit consumed life (hereinafter, MTTFm) defined by the following equation. Note that MTTFm indicates the ratio of the time consumed (operation time) of the piezo element 321 within the time interval, with respect to the expected life (mean time to failure), considering the conditions under which the piezo element 321 is used.

$$MTTFm = \frac{{T}_{int}}{MTTFs \times A ν ( m ) \times At ( m )} \qquad [ Equation 1 ]$$

Tᵢₙₜ is the time [hour] of the time interval, and is one hour in the embodiment. The MTTFs is a reference mean time to failure having been obtained in advance, through reliability tests.

Av(m) is an acceleration coefficient that is determined by a representative value (V_{R}) of a plurality of driving voltages included in the m-th time interval. Where, the acceleration coefficient Av can be expressed as(V₀/V_{R})^{k1}, for example. V₀ is a reference voltage under which the reference mean time to failure is obtained. k1 is a coefficient set by the user.

At(m) is an acceleration coefficient obtained by a representative value (T_{R}) of a plurality of temperatures included in the m-th time interval. Where, the acceleration coefficient At can be expressed as k2^{(T0-T)/10}, for example. T₀ is a reference temperature under which the reference mean time to failure is obtained. k2 is a coefficient set by the user. In the calculation of MTTFm, a preset fixed value may be used for one of the driving voltage and the temperature.

The life calculation unit 4e then takes the sum of the MTTFms obtained for respective time intervals. The sum (hereinafter, denoted as MTTFc) represents the cumulative consumed life from when the use of the piezo element 321 is started, and is expressed by the following equation. That is, the life calculation unit 4e according to the embodiment calculates the following MTTFc for each time interval. Note that MTTFc indicates the ratio of the total time consumed by the piezo element 321 (total operation time) to the expected life (average failure time), considering the conditions under which the piezo element 321 is used.

$$MTTFc = \frac{{T}_{int}}{MTTFs \times A ν ( 1 ) \times A t ( 1 )} + \frac{{T}_{int}}{MTTFs \times Av ( 2 ) \times At ( 2 )} + … + \frac{{T}_{int}}{MTTFs \times A v ( m ) \times A t ( m )} \qquad [ Equation 2 ]$$

When the MTTFc reaches one, the expected life (mean time to failure) giving consideration of the usage conditions expires.

The life calculation unit 4e may also be configured to output and display the calculated unit consumed life (MTTFm) or the cumulative consumed life (MTTFc) onto a display such as a user terminal. By outputting the calculated unit consumed life (MTTFm), it is possible to determine the conditions under which the piezo element 321 is used, or get a grasp of the tendency of the piezo element 321.

The life-related data storage unit 4f stores therein various types of data required for making a diagnosis of the life of the piezo element 321. The life-related data according to the embodiment is implemented as a nonvolatile memory, for example.

Specifically, the life-related data storage unit 4f stores therein the driving voltage applied to the piezo element 321, the temperature of the piezo element 321, MTTFs, MTTFm, MTTFc, the coefficients of Av and At (e.g., k1, k2), thresholds for an alarm output and an error output, which will be described later, and the like.

The stored driving voltage is a representative value of the driving voltages within the corresponding time interval or the immediately previous time interval. The temperature of the stored piezo element 321 is a representative value of the temperatures within the corresponding time interval or the immediately previous time interval. The representative value of the driving voltage and the representative value of the temperature are stored every time the time interval elapses (for example, every hour). The stored driving voltage or temperature may be a value corresponding to each sampling time period, instead of the representative value. When a fixed value is used for the driving voltage or the temperature in the life calculation unit 4e, the fixed value is stored in the life-related data storage unit 4f.

The stored MTTFs is a reference value obtained in advance through reliability tests. The stored MTTFm is a value having been immediately previously stored. The MTTFm may be stored correspondingly to each time interval. The stored MTTFc is the sum up to the previous time interval. The MTTFm and the MTTFc are stored every time the time interval elapses (for example, every hour).

The comparison unit 4g compares the consumed life or the remaining life calculated by the life calculation unit 4e with a predetermined threshold. The comparison unit 4g according to the embodiment compares the calculated cumulative consumed life with a predetermined threshold. Furthermore, the comparison unit 4g compares the calculated cumulative consumed life with a first threshold for outputting an alarm and a second threshold for outputting an error.

Because the life calculation unit 4e according to the embodiment calculates a cumulative consumed life (MTTFc), the first threshold and the second threshold are thresholds for the cumulative consumed life (MTTFc). For example, the first threshold for outputting an alarm is set to 0.6, and the second threshold for outputting an error is set to 0.8. The comparison unit 4g then compares MTTFc with each of these threshold every time the time interval elapses (for example, every hour).

The alarm output unit 4h outputs an alarm or an error on the basis of the comparison result of the comparison unit 4g (MTTFc ≥first threshold, MTTFc ≥second threshold). As a specific example, the alarm output unit 4h may be configured to output a signal for controlling a notification device that emits sound or light, or to display an alarm or an error on a display, such as a user terminal.

### <3. Advantageous Effects Achieved by Embodiment>

As described above, with the vaporization system 100 according to the embodiment, because the consumed life or the remaining life of the piezo element 321 is calculated based on the driving information, it is possible to replace or maintain the piezo element 321 at an appropriate timing even in an environment in which the condition of use of the piezo element changes. At this time, because the consumed life or the remaining life of the piezo element 321 is calculated using the reference mean time to failure (MTTFs) obtained in advance through reliability tests, the consumed life or the remaining life can be obtained more accurately. Furthermore, because the consumed life or the remaining life is calculated based on the driving voltage or the temperature that tends to have a great impact on the life of the piezo element 321, a more accurate consumed life or remaining life can be obtained.

### <4. Other Embodiments>

For example, as the cumulative consumed life of the piezo element 321, the life calculation unit 4e may calculate time instead of the ratio. In such a case, the used time is the sum of the time intervals described in the embodiment. For example, when the time interval is set to one hour, it is possible to calculate the time of usage (simply the time for which the piezo element is operated), by recording the number of the time intervals.

In order to calculate the cumulative consumed life more accurately, the life calculation unit 4e may also calculate a converted operation time that is a conversion assuming that the piezo element 321 is used under a certain driving condition (e.g., a certain driving voltage or driving temperature). Specifically, the life calculation unit 4e may calculate the converted operation time, as the consumed life, by multiplying the mean time to failure (MTTFr) used with a certain driving voltage and temperature, by the cumulative consumed life (MTTFc) obtained by Equation 2.

Furthermore, although calculated by the life calculation unit 4e according to the embodiment is the cumulative consumed life (MTTFc) of the piezo element 321, the remaining life (1-MTTFc) may be calculated by subtracting the cumulative consumed life (MTTFc) from one. In this case, the calculated remaining life is represented as a ratio.

Furthermore, the life calculation unit 4e may obtain time as the remaining life. For example, when the MTTFm is 0.4, the remaining life is 0.6. It is then necessary to convert 0.6 into time. In such a case, the remaining time can be calculated using the calculation formula of MTTFm, and the representative value of the driving voltage and the representative value of the temperature in the latest time interval, for example. When the remaining life (ratio) is 0.6, the remaining time a can be obtained by the following equation.

$$0.6 = α / ( MTTFs \times Av \times At )$$

The representative value of the driving voltage and the representative value of the temperature in the latest time interval are used as Av and At, respectively. It is also possible to use the representative value of the driving voltage and the representative value of the temperature in any one of the past time intervals, as Av and At, respectively. It is also possible to use preset fixed values as Av and At.

The life calculation unit 4e according to the embodiment calculates both of the unit consumed life and the cumulative consumed life of the piezo element 321, but may be configured to calculate only one of the unit consumed life and the cumulative consumed life. Even in the configuration in which only the unit consumed life is calculated, it is possible to determine the usage conditions or to get a grasp of a tendency of the piezo element 321 by observing how the unit consumed life changes.

In the embodiment described above, the comparison unit 4g and the alarm output unit 4h are provided, but the comparison unit 4g and the alarm output unit 4h may be omitted. In such a case, the user can replace or maintain the piezo element at an appropriate timing by outputting the cumulative consumed life or the remaining life calculated by the life calculation unit 4e onto a display such as a user terminal.

Furthermore, the expected life may be obtained from the number of times, the length of time, or the cumulative amount by which the piezo valve 32 (piezo element 321) is driven (moved), for example, and the life calculation unit 4e may calculate the consumed life or the remaining life on the basis of the expected life and the driving information.

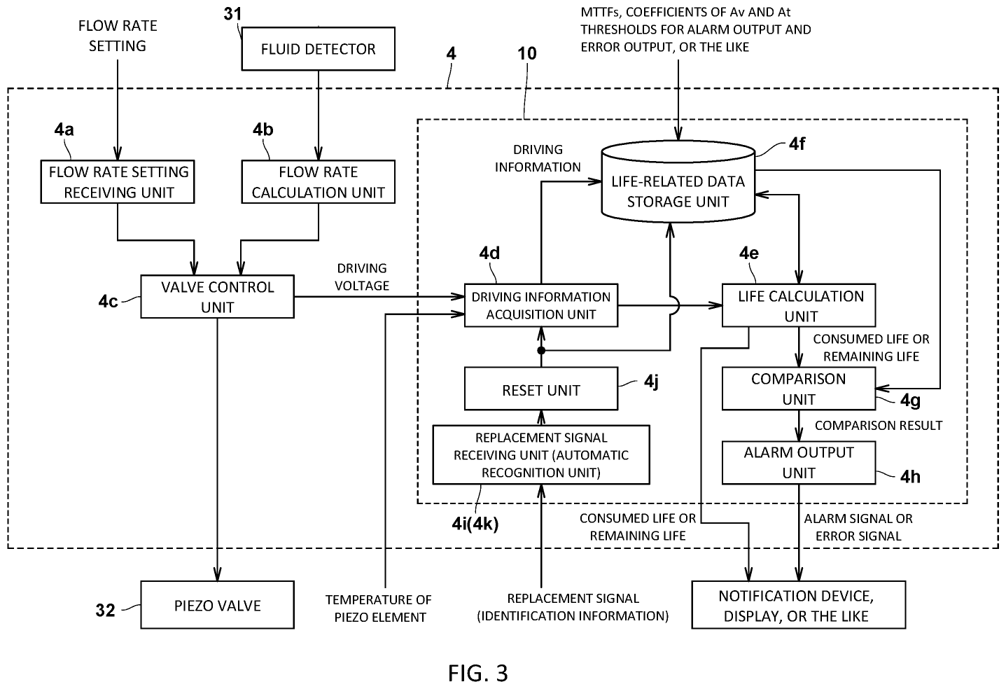

Further, as illustrated in FIG. 3, the control device 4 (piezo element diagnosis device 10) may include a replacement signal receiving unit 4i that receives a replacement signal indicating that the piezo element having been diagnosed has been replaced, and a reset unit 4j that resets the consumed life or the remaining life calculated by the life calculation unit 4e upon receiving the replacement signal. It is possible for the replacement signal to be entered by a user using some input device.

As illustrated in FIG. 3, the control device 4 (piezo element diagnosis device 10) may include, instead of the replacement signal receiving unit 4i, an automatic recognition unit 4k that automatically recognizes the replaced piezo element 321 when the piezo element 321 having been diagnosed is replaced. When a piezo valve 32 or a mass flow controller 3 (fluid control device) having a piezo element 321 is replaced, the automatic recognition unit 4k may automatically recognize the replaced piezo element 321, by receiving identification information from the replaced piezo valve 32 or the mass flow controller 3. In these cases, the life calculation unit 4e calculates the consumed life or the remaining life of the replaced piezo element 321 having been automatically recognized by the automatic recognition unit 4k. Furthermore, with such automatic recognition by the automatic recognition unit 4k, it is possible to manage the life-related data correspondingly to identification information, without causing the reset unit 4j to reset the information.

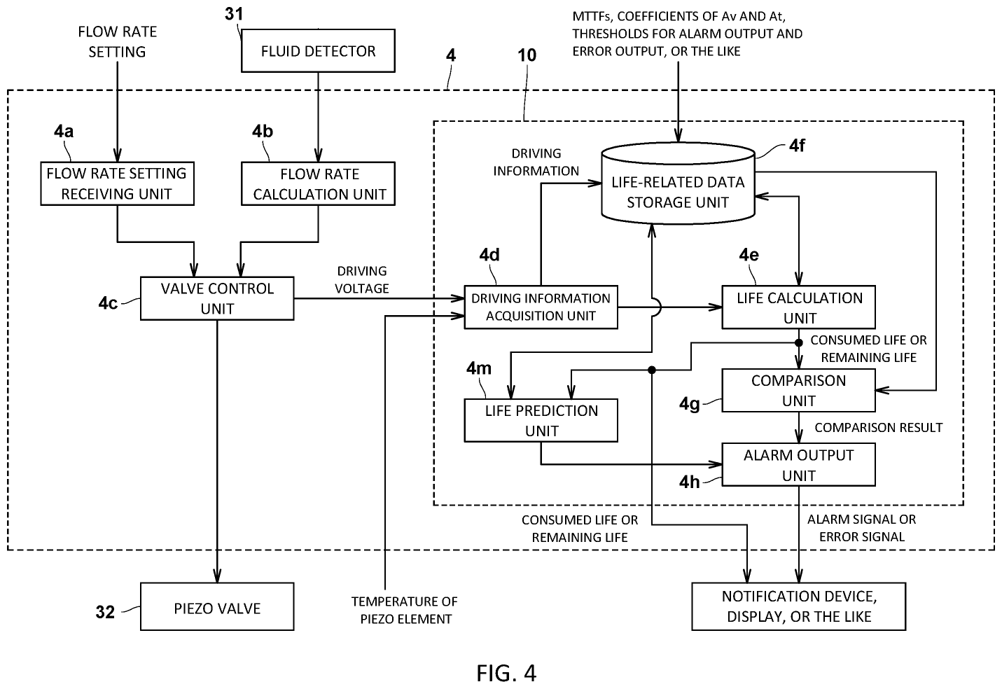

Furthermore, as illustrated in FIG. 4, the control device 4 (piezo element diagnosis device 10) may further include a life prediction unit 4m that calculates a future consumed life or remaining life based on a change in the consumed life or remaining life calculated by the life calculation unit 4e. Specifically, the life prediction unit 4m calculates the future consumed life or remaining life on the basis of a driving history, such as the frequency at which the piezo element is driven, in addition to a change in the consumed life or the remaining life calculated by the life calculation unit 4e. The life prediction unit 4m may also predict periods for which the thresholds used in the comparison unit will be reached, respectively, for example. Specifically, assuming that the piezo element will be kept using continuously under the conditions indicated by the driving information in a certain time interval, it is possible to predict that the first threshold (0.6) will be reached in one month, for example, if the current consumed life (MTTFc) is 0.5. The life prediction unit 4m may also predict a time period required for the mean time to failure to be reached. Furthermore, the life prediction unit 4m may be configured to issue an alarm command to the alarm output unit 4h.

The vaporization method may use bubbling vaporization, as well as any other vaporization methods such as thermal vaporization.

In addition, although the vaporizer unit 2 and the mass flow controller 3 according to the embodiment described above are configured to be mounted on the main body block 5, the main body block 5 may be configured to be separated from the vaporizer unit 2 and the mass flow controller 3. Furthermore, the vaporizer unit 2 and the mass flow controller 3 may be connected to each other via a pipe.

Furthermore, the vaporization system according to the embodiment described above supplies the material gas into the chamber of the semiconductor manufacturing apparatus, but may supply the material gas to another type of chamber.

Furthermore, the piezo element diagnosis device according to the embodiment described above is incorporated in the vaporization system but may be a device (module) of a system other than a vaporization system. Furthermore, the piezo element diagnosis device may be a device (module) different from a fluid control device.

In addition, the piezo element diagnosis device may diagnose a piezo element that is used to output a voltage by receiving an application of a pressure, in addition to the diagnosis of a piezo element used by being driven by receiving an application of a voltage.

Any other various modifications and combinations of the embodiment are still possible within the scope not deviating from the gist of the present invention.

### REFERENCE CHARACTERS LIST

100 vaporization system
2 vaporizer unit
3 fluid control device (mass flow controller)
32 piezo valve
321 piezo element
10 piezo element diagnosis device
4 control device
4c valve control unit
4d driving information acquisition unit
4e life calculation unit
4g comparison unit
4h alarm output unit
4i replacement signal receiving unit
4j reset unit
4k automatic recognition unit
4m life prediction unit

What is claimed is:

1. A piezo element diagnosis device for making a diagnosis of a piezo element incorporated in a piece of equipment, the piezo element diagnosis device comprising:
a driving information acquisition unit that acquires driving information of the piezo element; and
a life calculation unit that calculates a consumed life or a remaining life of the piezo element based on the driving information.

2. The piezo element diagnosis device according to claim 1, wherein the life calculation unit calculates the consumed life or the remaining life based on an expected life of the piezo element, the expected life being obtained in advance, as well as on the driving information.

3. The piezo element diagnosis device according to claim 2, wherein
the driving information includes at least one of a driving voltage of the piezo element and a temperature of the piezo element, and
the life calculation unit calculates the consumed life or the remaining life based on the expected life and at least one of the driving voltage of the piezo element and the temperature of the piezo element.

4. The piezo element diagnosis device according to claim 1, wherein the life calculation unit calculates a cumulative consumed life or the remaining life from when use of the piezo element is started, once in every time interval.

5. The piezo element diagnosis device according to claim 1, wherein the life calculation unit calculates a unit consumed life that is the life consumed per unit time, once in every time interval.

6. The piezo element diagnosis device according to claim 1, wherein
the driving information acquisition unit acquires the driving information once in every sampling time period, and
the life calculation unit calculates the consumed life or the remaining life by using a representative value of a plurality of pieces of the driving information.

7. The piezo element diagnosis device according to claim 1, further comprising:
a comparison unit that compares the consumed life or the remaining life calculated by the life calculation unit with a predetermined threshold; and
an alarm output unit that outputs an alarm based on a result of a comparison performed by the comparison unit.

8. The piezo element diagnosis device according to claim 1, further comprising:
a replacement signal receiving unit that receives a replacement signal indicating that a subject piezo element has been replaced; and
a reset unit that resets the consumed life or the remaining life calculated by the life calculation unit upon receiving the replacement signal.

9. The piezo element diagnosis device according to claim 1, further comprising an automatic recognition unit that automatically recognizes a piezo element after replacement when a subject piezo element is replaced, wherein
the life calculation unit calculates a consumed life or a remaining life of the piezo element after replacement.

10. The piezo element diagnosis device according to claim 1, further comprising a life prediction unit that calculates a future consumed life or remaining life based on a change in the consumed life or the remaining life obtained by the life calculation unit.

11. A piezo element diagnosis method for diagnosing a piezo element incorporated in a piece of equipment, the piezo element diagnosis method comprising:
acquiring driving information of the piezo element; and
calculating a consumed life or a remaining life of the piezo element based on the driving information.

12. A non-transitory computer-readable medium storing a piezo element diagnosis program for diagnosing a piezo element incorporated in a piece of equipment, the program executable by a computer to cause the computer to exert a function as:
a driving information acquisition unit that acquires driving information of the piezo element; and
a life calculation unit that calculates a consumed life or a remaining life of the piezo element based on the driving information.

13. A fluid control device comprising:
a piezo valve that uses a piezo element to drive a valve body with respect to a valve seat;
a valve control unit that controls a degree by which the piezo valve is opened; and
the piezo element diagnosis device according to claim 1.

14. A vaporization system comprising:
a vaporizer unit that vaporizes a liquid raw material;
a fluid control device that controls a flow rate of vapor resultant of vaporization of the vaporizer unit; and
the piezo element diagnosis device according to claim 1.
